(19) United States
(12) Patent Application Publication
(10) Pub. No.: US 2011/0033999 A1
(43) Pub. Date: Feb. 10, 2011

(54) DOPING METHOD, AND METHOD FOR PRODUCING SEMICONDUCTOR DEVICE

(75) Inventors: Tadahiro Kono, Kanagawa (JP); Akio Machida, Kanagawa (JP); Toshio Fujino, Kanagawa (JP)

Correspondence Address: SNR DENTON US LLP, P.O. BOX 061080, CHICAGO, IL, 60606-1080, US

(73) Assignee: SONY CORPORATION, Tokyo (JP)

(21) Appl. No.: 12/847,200

(22) Filed: Jul. 30, 2010

(30) Foreign Application Priority Data
Aug. 7, 2009 (JP) 2009-184205

(51) Int. Cl. H01L 21/336; H01L 21/22

(52) U.S. Cl. 438/305; 438/558; 257/E21.135; 257/E21.409

(57) ABSTRACT

A doping method includes: a first step of depositing a material solution containing an antimony compound containing elements selected from the group consisting essentially of hydrogen, nitrogen, oxygen, and carbon together with antimony to a surface of a substrate; a second step of drying the material solution to form an antimony compound layer on the substrate; and a third step of performing heat treatment so that antimony in the antimony compound layer is diffused into the substrate.

### BACKGROUND OF THE INVENTION

1. Field of the Invention

The preset invention relates to a doping method and a method for producing a semiconductor device, and especially to a method suitable for the production of a thin-film semiconductor device.

2. Description of the Related Art

The use of a lightweight, flexible plastic substrate as a supporting substrate in a semiconductor device including a thin-film semiconductor layer has been considered. In the production of such a semiconductor device, in consideration of the thermal resistance of the plastic substrate, a low-temperature process is desired. Therefore, also in the impurity doping of the semiconductor layer, a method that allows impurity doping at a low temperature has been considered as a substitute for ion implantation that requires high-temperature heat treatment to remove hydrogen. Further, with the increase in the size of the substrate, existing vacuum processes almost reach a limit in terms of the size of facilities therefore. In addition, existing ion implantation or like doping methods approach the limit of increase in the size in consideration of the takt, etc. For these reasons, for application to the impurity doping of the semiconductor layer, development of a new doping method that uses a vacuumless process capable of processing large areas has been desired.

As a first example of a novel doping method that is vacuumless and capable of processing large areas, a method in which an impurity-containing layer that contains phosphorus or boron is formed on a semiconductor layer and then irradiated with an energy beam to diffuse impurities from the impurity-containing layer into the semiconductor layer has been proposed. In this case, as the impurity-containing layer, a silicate glass containing phosphorus or boron (so-called PSG, BSG, etc.) is used (see, e.g., JP-A-62-2531) . As a second example, a method in which a liquid film of an impurity ion solution containing phosphorus or boron is formed on a semiconductor layer, dried, and then irradiated with an energy beam to diffuse impurities into the semiconductor layer has been proposed (see JP-A-2005-260040).

### SUMMARY OF THE INVENTION

However, it is difficult for the above doping methods to control the concentration of impurities used to dope the semiconductor layer. In the first example, silicon oxide in the silicate glass forming PSG or BSG is also taken into the semiconductor layer, resulting in property degradation of the semiconductor layer. Further, the second example does not allow high-concentration phosphorus (P) or boron (B) doping, and it thus is difficult to obtain a semiconductor device with desired properties by the above doping methods.

Thus, there is a need for a doping method compatible with a vacuumless (large-area processible), low-temperature process, which also allows the impurity concentration to be controlled with high accuracy without losing the semiconductor properties. There also is a need for a production method capable of providing a semiconductor device with well controlled property accuracy.

According to an embodiment of the invention, there is provided a doping method including the following steps. First, in a first step, a material solution containing an antimony compound that contains elements selected from the group consisting of hydrogen, nitrogen, oxygen, and carbon together with antimony is deposited to the surface of a substrate. Next, in a second step, the material solution is dried to form an antimony compound layer on the substrate. Subsequently, in a third step, heat treatment is performed to diffuse antimony in the antimony compound layer into the substrate.

According to another embodiment of the invention, there is provided a method for producing a semiconductor device. The method includes diffusing antimony into a semiconductor layer using the above doping method.

In accordance with such a method, antimony is diffused from the antimony compound layer containing elements selected from the group consisting of hydrogen, nitrogen, oxygen, and carbon, and antimony. Therefore, antimony can be diffused into the substrate without losing the properties of the substrate (semiconductor properties). Further, as described later in Examples, it has been confirmed that this method allows the substrate to be doped with antimony at a high concentration corresponding well to the antimony concentration of the material solution. Further, the heat treatment for diffusing antimony into the substrate is performed by energy beam irradiation. The method is thus compatible with a low-temperature process.

As described above, the doping method according to the embodiment of the invention is compatible with a vacuumless, low-temperature process, and also allows the impurity doping concentration to be controlled with high accuracy without losing the semiconductor properties. Further, use of such a method makes it possible to provide a semiconductor device with well controlled properties.

### BRIEF DESCRIPTION OF THE DRAWINGS

FIGS. 1A to 1E show a flow chart illustrating a doping method according to a first embodiment in cross section.

FIGS. 2A to 2E show a flow chart illustrating a method for producing a semiconductor device according to a second embodiment in cross section.

FIGS. 3A to 3E show a flowchart (I) illustrating a method for producing a semiconductor device according to a third embodiment in cross section.

FIGS. 4A to 4E show a flow chart (II) illustrating the method for producing a semiconductor device according to the third embodiment in cross section.

FIG. 5 is a graph showing the relation between the concentration of antimony solutions used in Example 1 and the carrier concentration of the resulting impurity regions.

FIG. 6 is a graph showing the Vg-Id characteristics of thin-film transistors produced in Example 2 and Comparative Example 2.

FIGS. 7A and 7B are graphs showing the Vg-Id characteristics of thin-film transistors produced in Example 3 and Comparative Examples 2 and 3.

### DESCRIPTION OF THE PREFERRED EMBODIMENTS

Hereinafter, embodiments of the invention will be described with reference to the drawings in the following order.

1. First Embodiment (Example of a doping method)

2. Second Embodiment (Example of a method for producing a semiconductor device including a gate insulating film with an offset)

3. Third Embodiment (Example of a method for producing a semiconductor device having a LDD structure)

### First Embodiment

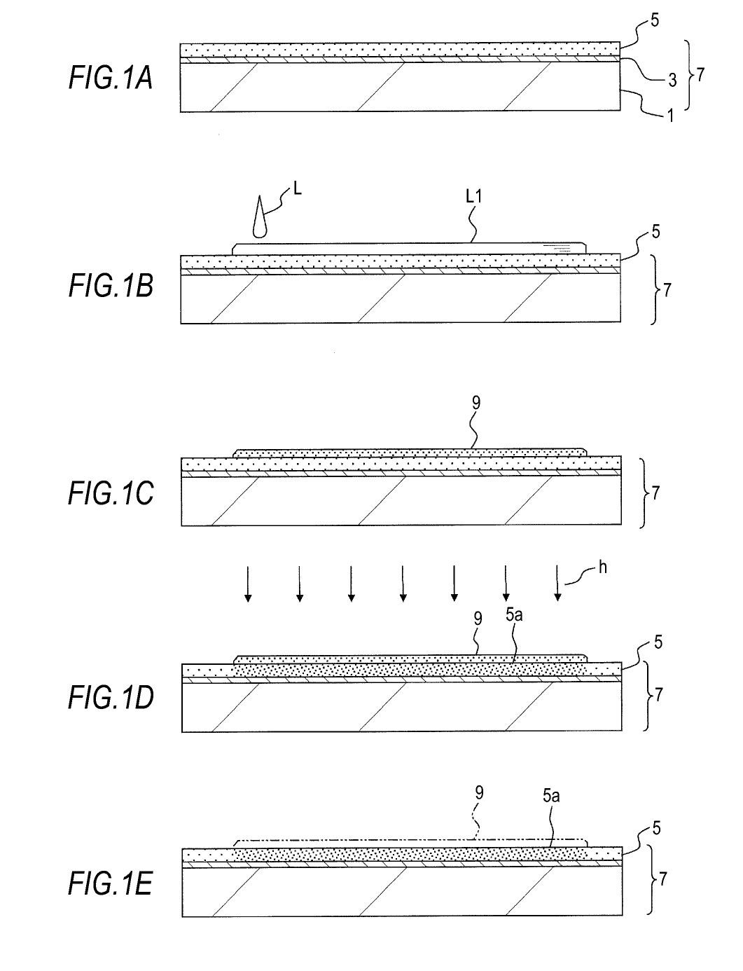

FIGS. 1A to 1E show a flow chart illustrating a doping method according to this embodiment in cross section. The following will describe the doping method based on these figures.

First, as shown in FIG. 1A, a supporting substrate 1 is prepared, and a buffer layer 3 made of an insulating material such as silicon oxide or silicon nitride is formed thereon. The supporting substrate 1 used here is a crystalline or amorphous substrate. Examples of crystalline substrates include a semiconductor substrate and a quartz substrate. Preferred examples of amorphous substrates include those that have low thermal resistance (low melting point) but allow the production of large-area substrates easily at low cost, such as those made of glass or an organic polymeric material (plastic). If necessary, the supporting substrate 1 may have flexibility.

Subsequently, a semiconductor layer 5 is formed on the supporting substrate 1 having formed thereon the buffer layer 3. The semiconductor layer 5 is made of amorphous silicon or microcrystal silicon, for example, and is formed about 50 nm thick. If necessary, the semiconductor layer 5 made of amorphous silicon or microcrystal silicon may be subjected to crystallization by laser beam irradiation, etc., giving polycrystalline silicon. The semiconductor layer 5 may also be patterned into islands for the isolation of devices. The structure including such a semiconductor layer 5 is referred to as a substrate 7.

In addition to the above examples, the semiconductor layer 5 may also be a deposit of a polysilane compound or a deposit of a polysilane compound polycondensate, for example. The semiconductor layer 5 is not limited to a silicon-based layer, and may alternatively be a film of any of various compound semiconductors, such as GaAs, GaN, or a like III-VI group compound semiconductors, ZnSe or a like II-V group semiconductors, etc. The semiconductor layer 5 made of any of these materials maybe formed/patterned by a method suitable for each material.

Next, as shown in FIG. 1B, an antimony solution L is deposited onto the substrate 7 having the semiconductor layer 5 formed on the surface thereof, thereby giving a solution layer L1. The antimony solution L is a material solution containing an antimony compound, and is prepared by dissolving an antimony compound in water or an organic solvent. The antimony compound used here is a compound containing elements selected from the group consisting of hydrogen, nitrogen, oxygen, and carbon together with antimony. Examples of such antimony compounds include antimony compounds with ligands containing hydrogen, nitrogen, oxygen and/or carbon atoms in the backbone, represented by the following formulae (1) to (14). However, in addition to carbon, hydrogen, nitrogen, oxygen, and antimony, the antimony compound may contain trace amounts of other substances mixed therein during the synthesis of the compound.

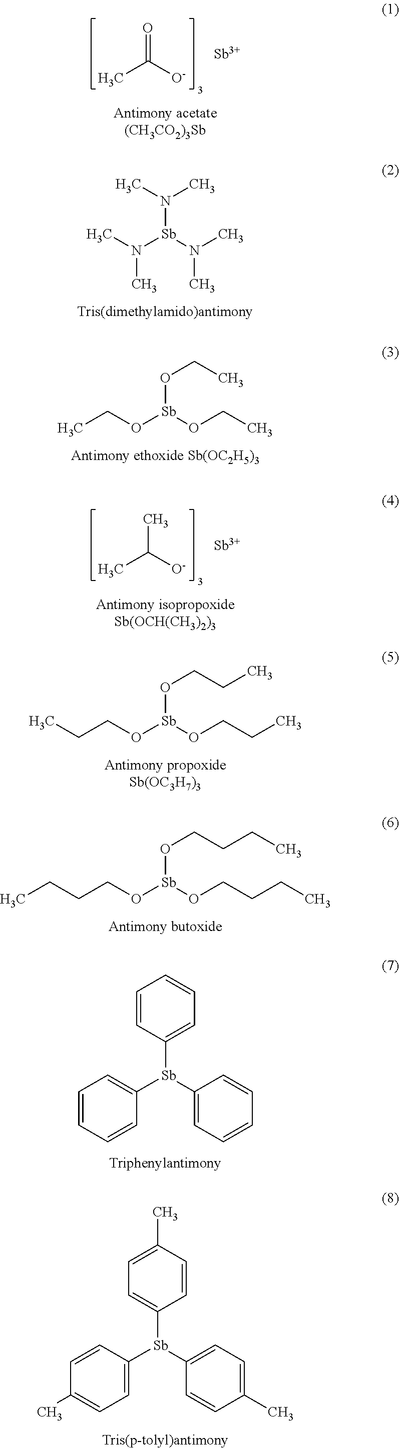

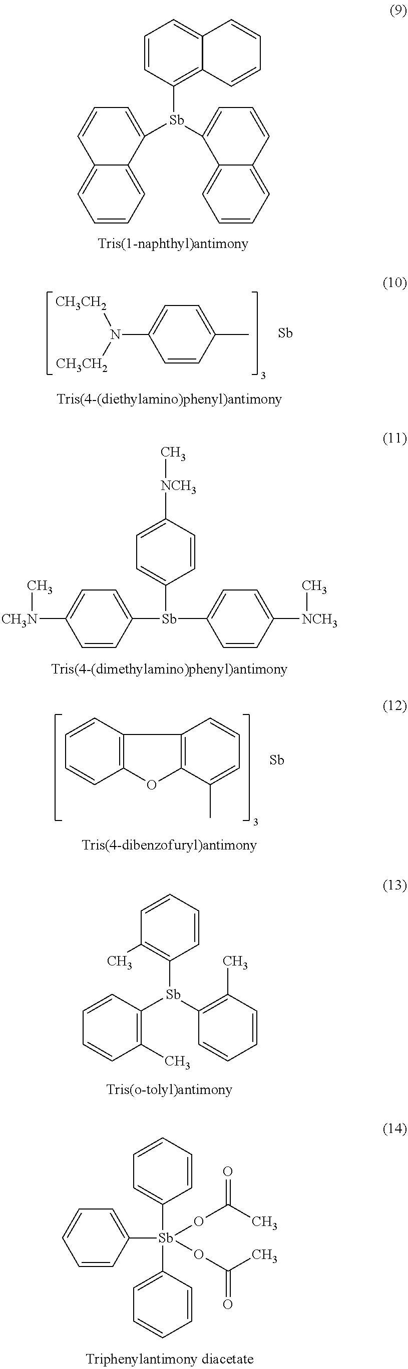

The concentration of the antimony compound in the antimony solution L is suitably controlled by the antimony doping concentration of the semiconductor layer 5. The doping concentration can be increased by increasing the concentration of the antimony compound.

Such an antimony solution L is deposited to the surface of the substrate 7 by coating, spraying (or atomizing), printing, or the like, thereby forming the solution layer L1. The printing method is not limited to contact printing, and various methods including imprinting, screen printing, gravure printing, offset printing, and the like are usable. Use of such a printing method makes it possible to pattern-form the solution layer L1 only in a specific area.

Next, as shown in FIG. 1C, the antimony solution layer L1 is dried to remove the solvent, and an antimony compound layer 9 containing the antimony compound is thus formed on the semiconductor layer 5. In this step, the solution layer L1 is dried by heating on a hot plate, for example. At this time, some solvent may remain in the antimony compound layer 9 unless it affects the energy beam irradiation during heat treatment performed in the following step. In the case where the solvent contains substances other than carbon, hydrogen, nitrogen, and oxygen, it is preferable that the solvent is removed as much as possible by evaporation; however, an unremovable, unintentional amount of solvent may remain therein.

Subsequently, as shown in FIG. 1D, antimony is diffused from the antimony compound layer 9 into the semiconductor layer 5 by heat treatment, whereby the semiconductor layer 5 is doped with antimony to form an impurity region 5a therein. It is preferable that the heat treatment is performed by irradiation with an energy beam h. This thus is a low-temperature process, in which the substrate temperature is kept low. The energy beam h may be selectively applied only to a target region where antimony is to be diffused, and may also be applied to a larger region including the target region or to the entire surface of the substrate 7. The energy beam h may be applied from the antimony-compound-layer-9 side. Alternatively, when the energy beam h can be transmitted from the supporting substrate 1 to the antimony compound layer 9, the energy beam h may be applied from the supporting-substrate-1 side.

The applied energy beam h may be a pulse, a continuous-wave laser beam, or an electron beam from an excimer laser, an YAG laser, a fiber laser, a ruby laser, an Ar laser, or a like laser, an infrared ray from an infrared lamp, a carbon heater, or the like, an ultraviolet ray from an ultraviolet ray lamp, etc. Further, in the case where the semiconductor layer 5 is amorphous, the semiconductor layer 5 may be crystallized simultaneously in this step.

After these steps, as shown in FIG. 1E, the antimony compound layer 9 is removed from the surface of the semiconductor layer 5. At this time, washing is performed with water or an organic solvent to remove the antimony compound layer 9.

In the case where a flexible material such as a plastic substrate is used as the supporting substrate 1, a roll-to-roll process may be used in any of the above steps. In the roll-to-roll process, for example, a transparent plastic film or a like tape-shaped substrate is wound around a first roller, and then, after the substrate is processed in a predetermined manner, the substrate is wound up by a second roller. As a result, this enables efficient processing within a short time, and thus is preferable.

In the above-described doping method, the heat treatment for diffusing antimony into the semiconductor layer 5 is performed by irradiation with the energy beam h. Therefore, doping by a low-temperature process is possible. Further, antimony is diffused from the antimony compound layer 9 containing elements selected from the group consisting of hydrogen, nitrogen, oxygen, and carbon, and antimony into the semiconductor layer 5. Therefore, antimony can be diffused without losing the properties of the semiconductor layer 5. Further, as described later in Examples, it has been confirmed that this method allows the semiconductor layer 5 to be doped with antimony at a high concentration corresponding well to the antimony concentration of the antimony solution L.

As a result, the doping method is compatible with a low-temperature process, and also allows the antimony doping concentration to be controlled with high accuracy without losing the semiconductor properties.

Further, because the formed antimony compound layer 9 contains elements selected from the group consisting of hydrogen, nitrogen, oxygen, and carbon, and antimony, when a metal electrode or the like is formed above the semiconductor layer 5 in a later step, the metal electrode is less likely to corrode.

Further, this doping method can be implemented without application of the vacuum process. Therefore, the production cost can be reduced, and it is also possible to treat a larger substrate.

The above embodiment describes a method in which the semiconductor layer 5 forming the surface of the substrate 7 is doped with antimony. However, the substrate (semiconductor substrate) made of a semiconductor material itself may be alternatively doped with antimony. In such a case, for example, the antimony compound layer 9 may be formed on a semiconductor substrate made of single-crystal silicon or a like crystalline semiconductor material, followed by energy beam irradiation. The surface of the semiconductor substrate can thus be doped with antimony with the concentration thereof being controlled with high accuracy.

### Second Embodiment

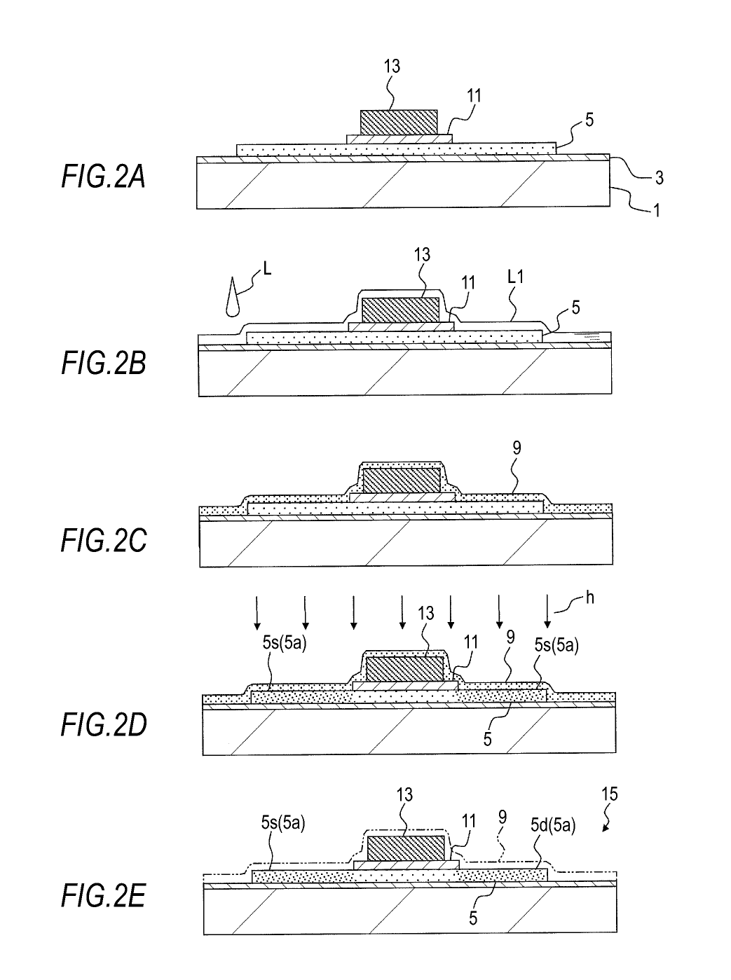

FIGS. 2A to 2E show a flow chart illustrating a method for producing a semiconductor device according to a second embodiment in cross section, which applies the doping method of the first embodiment. FIGS. 2A to 2E show the production of a semiconductor device configured as a thin-film transistor with an offset structure. The following describes the method for producing a semiconductor device based on these figures. The components common to the first embodiment are indicated with the same reference numerals, and will not be further described.

First, as shown in FIG. 2A, a semiconductor layer 5 is formed on a supporting substrate 1 with a buffer layer 3 therebetween, and, if necessary, the semiconductor layer 5 is patterned into islands and crystallized.

Next, across the semiconductor layer 5 in the form of islands, a gate insulating film 11 is formed above the supporting substrate 1 and then patterned. The gate insulating film 11 formed here is made of silicon oxide, silicon nitride, a silanol compound, a polycondensate thereof, etc. In particular, when the gate insulating film 11 is made of a silanol compound or a polycondensate thereof, a vacuumless process such as coating or printing can be applied to the film formation. It is also possible to employ printing to perform patterning.

Next, a gate electrode 13 is pattern-formed on the gate insulating film 11. In this step, the gate electrode 13 is pattern-formed at the center of the gate insulating film 11 so that the gate insulating film 11 is exposed on each side of the gate electrode 13 in the line width direction. The material for the gate electrode 13 formed here is not limited. For example, when a film made of a coating-type metal material or a metal-plated film is used, this is a vacuumless process, and it is also possible to employ printing to perform patterning.

The following steps shown in the FIGS. 2B to 2E are the same as described in the first embodiment with reference to FIG. 1B and the following figures.

That is, as shown in FIG. 2B, an antimony solution L is deposited to form a solution layer L1 above the supporting substrate 11 having formed thereon the gate insulating film 11 and the gate electrode 13 in such a manner that the solution layer L1 at least covers the exposed surface of the semiconductor layer 5 and also each edge of the gate insulating film 11. As described in the first embodiment, the antimony solution L is a material solution prepared by dissolving an antimony compound containing elements selected from the group consisting of hydrogen, nitrogen, oxygen, and carbon with antimony in a solvent. The concentration of the antimony compound is suitably controlled by the antimony doping concentration of the semiconductor layer 5.

Next, as shown in FIG. 2C, the antimony solution layer L1 is dried to remove the solvent, and an antimony compound layer 9 containing the antimony compound is thus formed on the semiconductor layer 5.

Subsequently, as shown in FIG. 2D, antimony is diffused from the antimony compound layer 9 into the semiconductor layer 5 by heat treatment, whereby the semiconductor layer 5 is doped with antimony to form an impurity region 5a therein. In this step, antimony is diffused into the semiconductor layer 5 on each side of the gate insulating film 11 and the gate electrode 13, thereby forming the impurity region 5a that serves as a source 5s and a drain 5d.

The heat treatment is performed in the same manner as described in the first embodiment, and is preferably performed by irradiation with an energy beam h. This thus is a low-temperature process, in which the substrate temperature is kept low. The energy beam h may be selectively applied only to a target region on each side of the gate insulating film 11 where antimony is to be diffused, and may also be applied to a larger region including the target region or to the entire surface of the supporting substrate 1. The energy beam h may be applied from the antimony-compound-layer-9 side. In such a case, the energy beam h is applied using the gate electrode 13 and the gate insulating film 11 as a mask. Alternatively, when the energy beam h can be transmitted from the supporting substrate 1 to the antimony compound layer 9, the energy beam h may be applied from the supporting-substrate-1 side. In such a case, the portion of the semiconductor layer 5 overlapping the gate electrode 13 and the gate insulating film 11 may be irradiated with the energy beam h so as to simultaneously crystallize the semiconductor layer 5.

After these steps, as shown in FIG. 2E, the antimony compound layer 9 is removed from the surface of the semiconductor layer 5. At this time, washing is performed with water or an organic solvent to remove the antimony compound layer 9.

A semiconductor device 15 configured as a thin-film transistor is thus provided, in which the semiconductor layer 5 has formed thereon the gate electrode 13 with the gate insulating film 11 therebetween. Subsequently, although not illustrated, an interlayer insulating film is formed over the entire surface of the supporting substrate 1, and a predetermined portion of the interlayer insulating film is removed by etching to form contact holes that reach the source 5s and the drain 5d. Then, after forming a film of an electrode material such as Al or an Al alloy, the electrode material is pattern-etched to form a source electrode and a drain electrode connected to the source 5s and the drain 5d, respectively, through the contact holes.

In accordance with the above-described production method, the impurity region 5a formed in the semiconductor layer 5 using the doping method of the first embodiment serves as the source 5s and the drain 5d. This provides an n-type source 5s/drain 5d with the antimony doping concentration being controlled with high accuracy without losing the semiconductor properties. Further, using as an offset the gate insulating film 11 protruding on each side of the gate electrode 13, the source 5s/drain 5d can be formed in a self-aligned manner. As a result, the semiconductor device 15 can be provided with well controlled properties.

### Third Embodiment

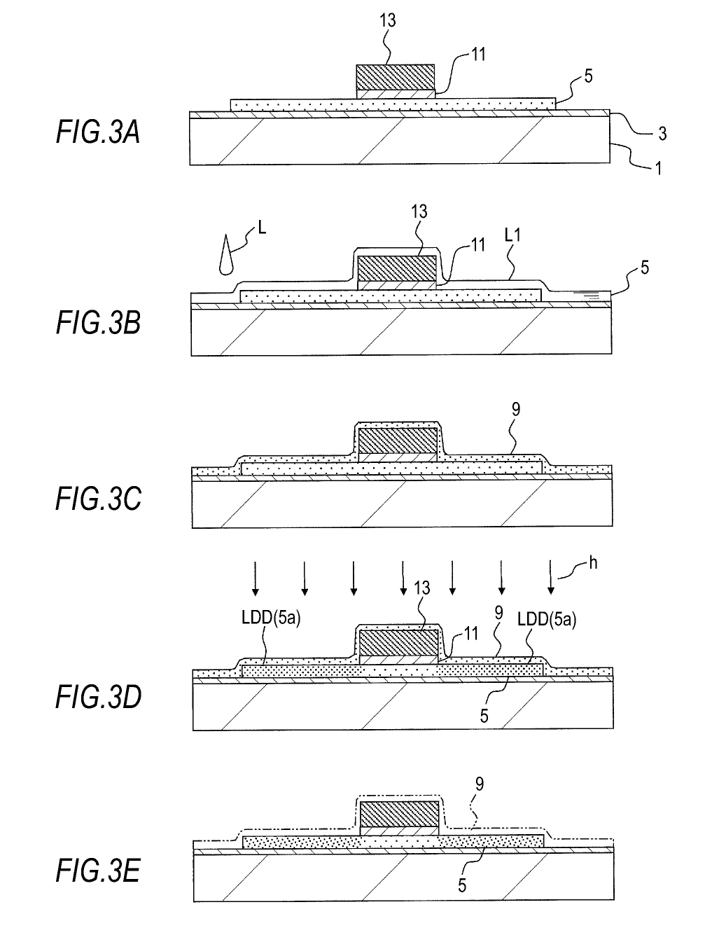

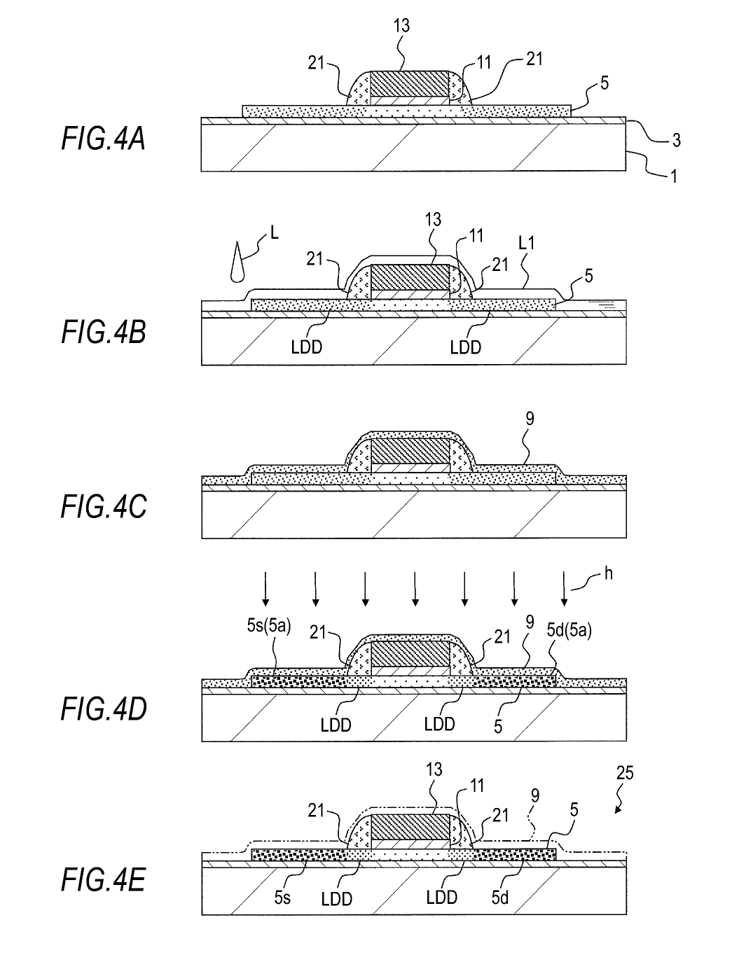

FIGS. 3A to 3E and 4A to 4E show a flow chart illustrating a method for producing a semiconductor device according to another embodiment in cross section, which applies the doping method of the first embodiment. These figures show the production of a semiconductor device configured as a thin-film transistor with a LDD structure. The following describes the method for producing a semiconductor device based on these figures. The components common to the first and second embodiments are indicated with the same reference numerals, and will not be further described.

First, as shown in FIG. 3A, a semiconductor layer 5 is formed on a supporting substrate 1 with a buffer layer 3 therebetween, and, if necessary, the semiconductor layer 5 is patterned into islands and crystallized.

Next, across the semiconductor layer 5 in the form of islands, a gate insulating film 11 and a gate electrode 13 are formed in the same pattern above the supporting substrate 1. The gate insulating film 11 is made of silicon oxide, silicon nitride, a silanol compound, a polycondensate thereof, etc. In particular, when the gate insulating film 11 is made of a silanol compound or a polycondensate thereof, a vacuumless process such as coating or printing can be applied to the film formation. The material for the gate electrode 13 is not limited. For example, when a film made of a coating-type metal material or a metal-plated film is used, this is a vacuumless process, and it is also possible to employ printing to perform patterning. In order to form the gate insulating film 11 and the gate electrode 13 in the same pattern, it is preferable to form and stack the gate insulating film 11 and a gate electrode film, and then pattern-etch them using the same mask.

After these steps, first, the steps shown in the FIGS. 3B to 3E are performed in the same manner as described in the first embodiment with reference to FIG. 1B and the following figures, thereby forming a low-concentration region (LDD) as follows.

That is, as shown in FIG. 3B, an antimony solution L containing an antimony compound at a low concentration is used to form a solution layer L1 above the supporting substrate 11 having formed thereon the gate insulating film 11 and the gate electrode 13 in such a manner that the solution layer L1 at least covers the exposed surface of the semiconductor layer 5. As described in the first embodiment, the antimony solution L is a material solution prepared by dissolving an antimony compound containing elements selected from the group consisting of hydrogen, nitrogen, oxygen, and carbon with antimony in a solvent. The concentration of the antimony compound is suitably controlled by the antimony doping concentration of the semiconductor layer 5, and is made low is this embodiment.

Next, as shown in FIG. 3C, the antimony solution layer L1 is dried to remove the solvent, and an antimony compound layer 9 containing the antimony compound is thus formed on the semiconductor layer 5.

Subsequently, as shown in FIG. 3D, antimony is diffused from the antimony compound layer 9 into the semiconductor layer 5 by heat treatment, whereby the semiconductor layer 5 is doped with antimony to form an impurity region 5a therein. In this step, antimony is diffused at a low concentration into the semiconductor layer 5 on each side of the gate insulating film 11 and the gate electrode 13, forming the impurity region 5a that serves as the low-concentration region LDD.

The heat treatment is performed in the same manner as described in the first embodiment, and is preferably performed by irradiation with an energy beam h. This thus is a low-temperature process, in which the substrate temperature is kept low. The energy beam h may be selectively applied only to a target region on each side of the gate insulating film 11 where antimony is to be diffused, and may also be applied to a larger region including the target region or to the entire surface of the supporting substrate 1. The energy beam h may be applied from the antimony-compound-layer-9 side. In such a case, the energy beam h is applied using the gate electrode 13 and the gate insulating film 11 as a mask. Alternatively, when the energy beam h can be transmitted from the supporting substrate 1 to the antimony compound layer 9, the energy beam h may be applied from the supporting-substrate-1 side. In such a case, the portion of the semiconductor layer 5 overlapping the gate electrode 13 and the gate insulating film 11 may be irradiated with the energy beam h so as to simultaneously crystallize the semiconductor layer 5.

After these steps, as shown in FIG. 3E, the antimony compound layer 9 is removed from the surface of the semiconductor layer 5. At this time, washing is performed with water or an organic solvent to remove the antimony compound layer 9.

Next, as shown in FIG. 4A, a sidewall 21 with insulating properties is formed on the side of the gate insulating film 11 and the gate electrode 13. Subsequently, as shown in FIG. 4B to FIG. 4E, the step of forming an impurity region using an antimony solution L is performed again.

That is, as shown in FIG. 4B, an antimony solution L containing an antimony compound is used to form a solution layer L1 above the supporting substrate 1 having formed thereon the gate insulating film 11, the gate electrode 13, and the sidewall 21 in such a manner that the solution layer L1 at least covers the exposed surface of the semiconductor layer 5. As described in the first embodiment, the antimony solution L is a material solution prepared by dissolving an antimony compound containing elements selected from the group consisting of hydrogen, nitrogen, oxygen, and carbon with antimony in a solvent. The concentration of the antimony compound is suitably controlled by the antimony doping concentration of the semiconductor layer 5, and is made higher than in the low-concentration region LDD.

Next, as shown in FIG. 4C, the antimony solution layer L1 is dried to remove the solvent, and an antimony compound layer 9 containing the antimony compound is thus formed on the semiconductor layer 5.

Subsequently, as shown in FIG. 4D, antimony is diffused from the antimony compound layer 9 into the semiconductor layer 5 by heat treatment, whereby the semiconductor layer 5 is doped with antimony to form an impurity region 5a therein. In this step, antimony is diffused into the semiconductor layer 5 outside the sidewall 21 at a higher concentration than in the low-concentration region LDD, thereby forming the impurity region 5a that serves as a source 5s and drain 5d. The low-concentration region LDD remains beneath the sidewall 21.

The heat treatment is carried out in the same manner as described in the first embodiment, and is preferably performed by irradiation with an energy beam h. This thus is a low-temperature process, in which the substrate temperature is kept low. The energy beam h may be selectively applied only to a target region outside the sidewall 21 where antimony is to be diffused, and may also be applied to a larger region including the target region or to the entire surface of the supporting substrate 1. The energy beam h maybe applied from the antimony-compound-layer-9 side. In such a case, the energy beam h is applied using the gate electrode 13 and the gate insulating film 11 as a mask. Alternatively, when the energy beam h can be transmitted from the supporting substrate 1 to the antimony compound layer 9, the energy beam h may be applied from the supporting-substrate-1 side. In such a case, the portion of the semiconductor layer 5 overlapping the gate electrode 13, the gate insulating film 11, and the sidewall 21 may be irradiated with the energy beam h so as to simultaneously crystallize the semiconductor layer 5.

A semiconductor device 25 configured as a thin-film transistor is thus provided, in which the semiconductor layer 5 has formed thereon the gate electrode 13 with the gate insulating film 11 therebetween and also has the low-concentration region LDD. Subsequently, although not illustrated, an interlayer insulating film is formed over the entire surface of the supporting substrate 1, and a predetermined portion of the interlayer insulating film is removed by etching to form contact holes that reach the source 5s and the drain 5d. Then, after forming a film of an electrode material such as Al or an Al alloy, the electrode material is pattern-etched to form a source electrode and a drain electrode connected to the source 5s and the drain 5d, respectively, through the contact holes.

In accordance with the above-described production method, the impurity region 5a formed in the semiconductor layer 5 using the doping method of the first embodiment serves as the source 5s and the drain 5d. This provides an n-type low-concentration region LDD, as well as an n-type source 5s/drain 5d having a higher concentration, with the antimony doping concentration being controlled with high accuracy without losing the semiconductor properties. The low-concentration region LDD and the source 5s/drain 5d are formed in a self-aligned manner using the gate electrode 13 and the sidewall 21 as a mask. The semiconductor device 25 can thus be provided with well controlled properties.

The thus-obtained semiconductor device is suitable for use as a device for driving a pixel in a display, for example.

Application of the above-described method for producing a semiconductor device is not limited to the production of a semiconductor device configured as a thin-film transistor. The method is applicable to the production of any semiconductor device, which includes the step of impurity doping, providing the same effects. Examples of such semiconductor devices include a solar cell and a photoreceptor. The method is also applicable to the production of a display using a thin-film transistor as a device for driving a pixel electrode, for example.

### Example 1

A semiconductor layer was doped with antimony to give an impurity region as follows (see FIGS. 1A to 1E).

First, a buffer layer 3 was formed on a glass substrate 1. On the buffer layer 3, a 50-nm-thick semiconductor layer made of amorphous silicon was formed. Next, the semiconductor layer 5 was irradiated with a laser beam to crystallize the amorphous silicon forming the semiconductor layer 5.

Subsequently, triphenyl antimony was dissolved in cyclohexane at a predetermined concentration to give an antimony solution L. A coating of the antimony solution L was applied onto a substrate 7 covered with the semiconductor layer 5 to give a solution layer L1. The substrate 7 was then heated on a hot plate or otherwise treated to dry the solution layer L1, giving an antimony compound layer 9.

The antimony compound layer 9 was irradiated with an excimer laser beam h (310 mJ) to diffuse antimony into the semiconductor layer 5, thereby forming an impurity region 5a.

### Evaluation 1

FIG. 5 is a graph showing to the carrier concentration measured for each impurity region 5a relative to the antimony concentration of the antimony solution L used to form the impurity region 5a. As shown in the figure, there is a high correlation between the carrier concentration (impurity concentration) of the impurity regions 5a and the antimony concentration of the antimony solutions L, and it was confirmed that the embodiments of the invention allow the antimony doping concentration to be controlled with high accuracy.

### Comparative Example 1

A semiconductor layer was doped with phosphorus to form an impurity region in the same manner as in Example 1, except that the antimony solution prepared by dissolving triphenyl antimony used in Example 1 was replaced with a solution prepared by dissolving triphenyl phosphine in cyclohexane to a concentration of 0.01 mol/L.

### Evaluation 2

With respect to one of the impurity regions of Example 1, which was formed using triphenyl antimony at a concentration of 0.01 mol/L, and the impurity region of Comparative Example 1 formed using the triphenyl phosphine at the same concentration, the surface resistance of each region was measured. Table 1 below shows the measurement results.

TABLE 1

| | Example 1 | Comparative Example 1 |
|---|---|---|
| Surface resistance | 367 | 3430 |
| (Ω/sq) | | |

As is obvious from Table 1, the impurity region produced in Example 1 has lower surface resistance by about one order of magnitude than the impurity region produced by Comparative Example 1, indicating that the embodiment of the invention enables impurity (antimony) doping at high concentration.

Generally, phosphorus has a higher solid-phase diffusion coefficient in silicon. However, when impurities are diffused from an impurity layer formed on a semiconductor layer by laser beam irradiation, the impurities on the semiconductor layer are not entirely dissolved into the semiconductor layer, and some are simultaneously sublimated by energy of the laser beam. In the case where the impurities are phosphorus, because phosphorus is a light element, the sublimation reaction caused by the laser beam is dominant, and this prevents phosphorus from efficiently dissolving into the semiconductor layer. In contrast, antimony is a heavy element and is hardly sublimated by laser beam irradiation, and thus can efficiently dissolve into the semiconductor layer.

In addition, the elements carbon, hydrogen, oxygen, and nitrogen forming the antimony compound used in the invention are much lighter than phosphorus. Therefore, as compared with antimony, much smaller amounts are taken into the semiconductor layer. Accordingly, the effects of these elements themselves can be suppressed, and the properties of the semiconductor layer 5 are maintained.

### Example 2 and Comparative Example 2

Semiconductor devices configured as thin-film transistors having the same specifications were produced as follows (see FIGS. 3A to 3E) . First, a buffer layer 3 was formed on a glass substrate 1. On the buffer layer 3, a 50-nm-thick semiconductor layer 5 made of amorphous silicon was formed. Next, the semiconductor layer 5 was irradiated with a laser beam to crystallize the amorphous silicon forming the semiconductor layer 5.

Next, a gate insulating film 11 was formed on the semiconductor layer 5, and a gate electrode film was then formed. The films were simultaneously patterned to give a gate electrode 13.

Subsequently, in Example 2, the same procedure as in Example 1 was performed to form an impurity region 5a by antimony doping in a self-aligned manner on each side of the gate electrode 13, which serves as a source 5s and a drain 5d. The antimony solution used was prepared at a triphenyl antimony concentration of 0.005 mol/L. In Comparative Example 2, ion implantation was applied to the source/drain formation. At this time, the dose was controlled so that the resulting source/drain was at the same level as the source/drain of Example 2.

### Evaluation 3

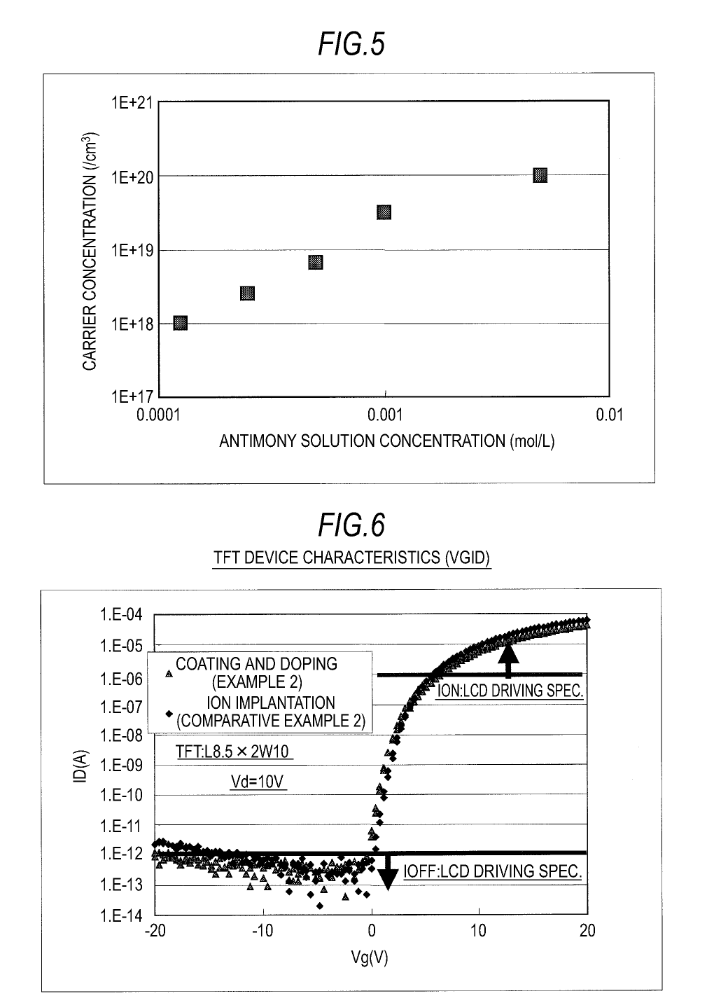

FIG. 6 shows the gate voltage (Vg)-drain current (Id) characteristics of the thin-film transistors produced in Example 2 and Comparative Example 2. As shown in the figure, it was confirmed that the thin-film transistor of Example 2 produced in accordance with an embodiment of the invention shows excellent transistor characteristics comparable to the case of Comparative Example 2 where ion implantation was applied.

### Example 3 and Comparative Examples 3 and 4

Semiconductor devices configured as thin-film transistors having the same specifications were produced. In Example 3, a method according to an embodiment of the invention was applied to the source/drain formation, in which a coating of triphenyl antimony solution was applied, followed by diffusion. In Comparative Example 3, ion implantation was applied to the source/drain formation. At this time, the dose was controlled so that the resulting source/drain was at the same level as the source/drain of Example 3. In Comparative Example 4, a method including applying a phosphorus-containing SOG film, followed by diffusion of phosphorus, was applied to the source/drain formation.

### Evaluation 4

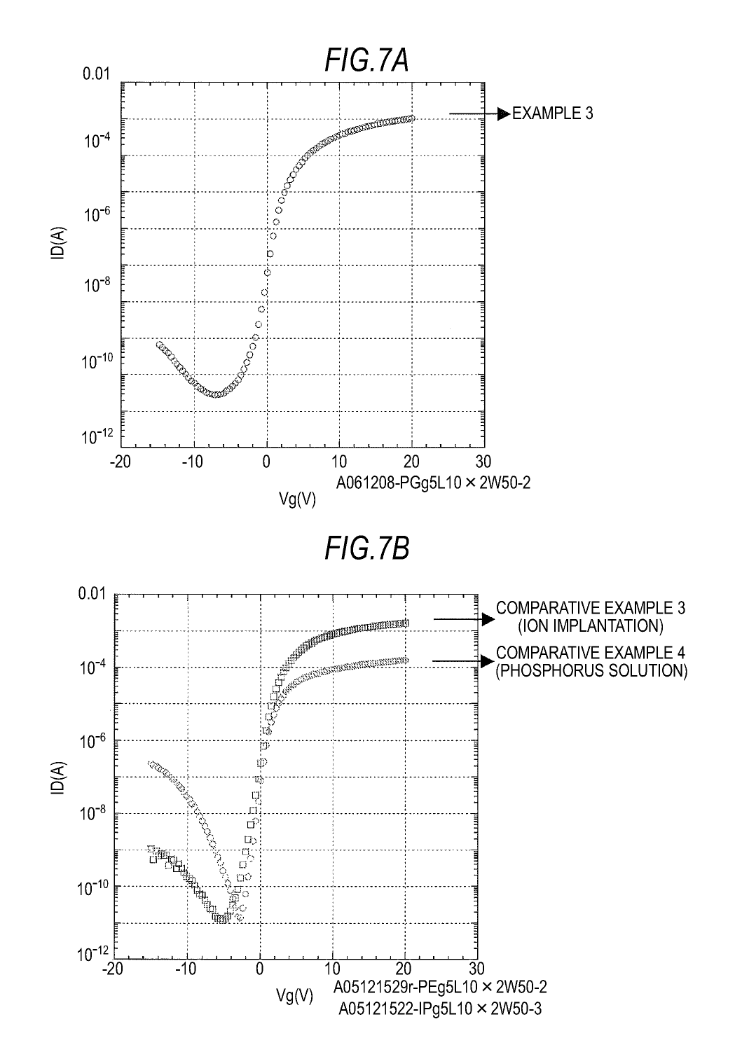

FIG. 7A shows the gate voltage (Vg)-drain current (Id) characteristics of the thin-film transistor produced in Example 3. FIG. 7B shows the gate voltage (Vg)-drain current (Id) characteristics of the thin-film transistors produced in Comparative Examples 3 and 4.

As is obvious from these figures, the thin-film transistor of Example 3 produced in accordance with the embodiment of the invention allows the source/drain impurity concentration to be well controlled, and also shows excellent transistor characteristics comparable to the case of Comparative Example 3 where ion implantation was applied.

In contrast, as compared with the thin-film transistor of Example 3 and the thin-film transistor of Comparative Example 3 produced applying the ion implantation, the thin-film transistor of Comparative Example 4 produced utilizing phosphorus diffusion from a phosphorus-containing SOG film has a lower ON-state current but exhibits a higher OFF-state current. This is attributable to the fact that during the diffusion of phosphorus from the phosphorus-containing SOG film into the semiconductor layer, silicon and other elements forming SOG were also diffused into the semiconductor layer, causing defects in the semiconductor layer. It was thus confirmed that at the time of impurity (antimony) diffusion into a semiconductor layer, it is important for the antimony compound formed on the semiconductor layer to contain elements selected from the group consisting hydrogen, nitrogen, oxygen, and carbon with antimony.

The present application contains subject matter related to that disclosed in Japanese Priority Patent Application JP 2009-184205 filed in the Japan Patent Office on Aug. 7, 2009, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A doping method comprising:
a first step of depositing a material solution containing an antimony compound containing elements selected from the group consisting of hydrogen, nitrogen, oxygen, and carbon together with antimony to a surface of a substrate;
a second step of drying the material solution to form an antimony compound layer on the substrate; and
a third step of performing heat treatment so that antimony in the antimony compound layer is diffused into the substrate.

2. A doping method according to claim 1, wherein the heat treatment is performed by irradiation of the antimony compound layer with an energy beam.

3. A doping method according to claim 1 or 2, wherein the material solution is deposited to the surface of the substrate by coating, spraying, or printing.

4. A doping method according to any one of claims 1 to 3, wherein the concentration of antimony diffused into the substrate is controlled by the antimony concentration of the material solution.

5. A doping method according to any one of claims 1 to 4, wherein the surface of the substrate is formed of a semiconductor layer.

6. A doping method according to any one of claims 1 to 5, wherein the antimony compound layer is removed after the heat treatment.

7. A method for producing a semiconductor device, comprising:
a first step of depositing a material solution containing an antimony compound containing elements selected from the group consisting essentially of hydrogen, nitrogen, oxygen, and carbon together with antimony to a surface of a semiconductor layer;
a second step of drying the material solution to form an antimony compound layer on the semiconductor layer; and
a third step of performing heat treatment so that antimony in the antimony compound layer is diffused into the semiconductor layer.

8. A method for producing a semiconductor device according to claim 7, wherein
a gate insulating film and a gate electrode are stacked in this order on the semiconductor layer prior to the first step, and
the material solution is deposited to the surface of the semiconductor layer on each side of the gate insulating film and the gate electrode in the first step.

9. A method for producing a semiconductor device according to claim 8, wherein
the antimony compound layer is removed to form a sidewall on the side of the gate insulating film and the gate electrode after the third step, and
the first step, the second step, and the third step are repeated so that the antimony is diffused into the semiconductor layer outside the sidewall at a higher concentration than in the semiconductor layer beneath the sidewall.
